(19) United States
(12) Patent Application Publication
(10) Pub. No.: US 2018/0248540 A1
(43) Pub. Date: Aug. 30, 2018

(54) SWITCHING CIRCUIT

(71) Applicant: PANASONIC INTELLECTUAL PROPERTY MANAGEMENT CO., LTD., Osaka (JP)

(72) Inventors: Takuya ISHII, Osaka (JP); Daijiro ARISAWA, Kyoto (JP); Masanori ITO, Hyogo (JP); Takao HASHIMOTO, Osaka (JP); Takeshi AZUMA, Osaka (JP); Miwa ISHITSUBO, Tokyo (JP); Kazuhiro MURATA, Hyogo (JP)

(21) Appl. No.: 15/965,007

(22) Filed: Apr. 27, 2018

Related U.S. Application Data
(63) Continuation of application No. PCT/JP2016/004810, filed on Nov. 4, 2016.

(30) Foreign Application Priority Data
Nov. 9, 2015 (JP) 2015-219921

(51) Int. Cl. H03K 3/013; H03K 17/16; H05K 1/18

(52) U.S. Cl. CPC H03K 3/013; H05K 2201/10166; H05K 1/181; H03K 17/161

(57) ABSTRACT

A switching circuit includes main switching a device and a drive circuit. The main switching device has a gate terminal, a drain terminal, and a first source terminal through which a main current flows, and a second source terminal for gate drive connected to drive circuit. The drive circuit has a bias capacitor having a negative electrode terminal connected to the second source terminal, a first series circuit formed between a positive electrode terminal and the gate terminal by connecting a high-side switch, a resistor, and a capacitor in series, and a second series circuit formed between the gate terminal and the second source terminal by connecting the capacitor, a resistor and a low-side switch in series. The drive circuit adjusts each of gate charge and discharge currents, and further damps the oscillation of the waveform of gate current/voltage.

### CROSS REFERENCE TO RELATED APPLICATIONS

This application is a U.S. continuation application of PCT International Patent Application Number PCT/JP2016/004810 filed on Nov. 4, 2016, claiming the benefit of priority of Japanese Patent Application Number 2015-219921 filed on Nov. 9, 2015, the entire contents of which are hereby incorporated by reference.

### BACKGROUND

### 1. Technical Field

The present disclosure relates to a switching circuit including a switching device and a drive circuit for the switching device.

### 2. Description of the Related Art

In power converters represented by switching power supplies or inverters, when a switching frequency is increased, LC components can be miniaturized. For this reason, development of a switching circuit capable of higher frequency switching is desired.

In recent years, as the switching device, attention is focused on gallium nitride gate injection transistors (GaN-GIT) that achieve a normally-off operation, a high current, and a low on-resistance at the same time, for instance, by using GaN (gallium nitride) which is a wide band gap compound semiconductor. Hereinafter in the present description, a high-speed switching device represented by GaN-GIT is referred to as a GaN transistor.

FIG. 6 is a circuit diagram of the semiconductor circuit described in Japanese Unexamined Patent Application Publication No. 2011-77462, which discloses a switching circuit including normally-off junction FET and a drive circuit for junction FET and having characteristics similar to the characteristics of GaN transistor mentioned above. Normally-off junction FET 101 is disposed between drain terminal 104, and source terminals 105a, 105b, and gate drive circuit 103 is disposed between gate terminal 106 and source terminal 105b. Gate drive circuit 103 includes gate resistor 111, gate power supply 112, and capacitor 115. FET 101 has parasitic diode 109 in parallel with input capacitance 108 between the gate and source. A threshold for turning on FET 101 is approximately 2.5V, and diode 113 and zener diode 114 are connected between gate terminal 106 and source terminal 105b of FET 101, and thus gate-source voltage is controlled. A charge and discharge current of input capacitance 108 is adjusted by gate resistor 111, and capacitor 115 is connected in parallel with gate resistor 111, and a charging current of input capacitance 108 is thereby passed along an another path not through gate resistor 111 to achieve high-speed turn-on. On the other hand, at the time of OFF, the voltage of capacitor 115, which is charged at the time of ON, is applied between the gate and source as a negative voltage. Thus, it is possible to prevent malfunction of performing ON operation due to an increase in the gate voltage caused by a charging current of parasitic capacitance 107 between the drain and gate, which flows associated with an increase in the voltage at drain terminal 104 at the time of turn-off.

Furthermore, the source electrode of junction FET 101 is connected via a wire to each of source terminal 105a and source terminal 105b, and gate terminal 106 and source terminal 105b are connected to gate drive circuit 103, thereby making it possible to separate a main circuit current which flows from drain terminal 104 to source terminal 105a from a path of gate current which flows from gate drive circuit 103. For this reason, the current of a main circuit hardly flows through a wire between gate terminal 106 and source terminal 105b, and thus the effect on the voltage by inductance 118 of the source wiring is reduced, thereby achieving a configuration that is unlikely to cause malfunction.

### SUMMARY

However, in the above-described switching circuit in related art, gate power supply 112 and gate terminal 106 are directly connected by capacitor 115, and thus it is difficult to supply a stable drive current while adjusting a switching speed. Although the effect of the parasitic inductance on the source wiring can be removed by branching the source terminal of the switching device, a parasitic inductance is present between the gate electrode and the gate terminal as well as between the source electrode and the source terminal, and thus a flow of the charge and discharge current of the capacitor without being adjusted causes the parasitic inductance to generate a voltage, which may bring a possibility of malfunction.

The present disclosure has been made in light of the above-mentioned problems, and it is an object of the disclosure to provide a switching circuit capable of performing a switching operation which is stably controlled by adjusting a switching speed of a high-speed switching device, and reducing the parasitic inductance in a drive circuit or damping the effect on the drive circuit by the parasitic inductance.

Hereinafter, the switching device included in the switching circuit of the present disclosure is referred to as the main switching device.

In order to solve the above-mentioned problems, a switching circuit according to an aspect of the present disclosure includes: a main switching device; and a drive circuit. The main switching device includes: a drain electrode; a gate electrode; and a source electrode. When the main switching device is in an ON state where a voltage higher than or equal to a threshold voltage is applied between the gate electrode and the source electrode, a main current flows between the drain electrode and the source electrode. The main switching device further includes: a gate terminal connected to the gate electrode; a drain terminal connected to the drain electrode; a first source terminal which is connected to the source electrode and through which the main current flows; and a second source terminal for gate drive connected to the source electrode and the drive circuit. The drive circuit includes: a bias voltage source having a positive electrode terminal and a negative electrode terminal connected to the second source terminal; a first series circuit formed between the positive electrode terminal and the gate terminal by connecting a first switch element, a first resistor, and a capacitor in series; and a second series circuit formed between the gate terminal and the second source terminal by connecting the capacitor, a second resistor, and a second switch element in series. When the first switch element is in an ON state, and a current flows through a turn-on loop formed by the bias voltage source, the first series circuit, and the main switching device, even when a voltage drop occurs in the turn-on loop by a first parasitic inductance present in the turn-on loop, the voltage between the gate electrode and the source electrode is maintained at a voltage higher than or equal to the threshold voltage, and when the second switch element is in an ON state, and a current flows through a turn-off loop formed by the main switching device and the second series circuit, even when a voltage drop occurs in the turn-off loop by a second parasitic inductance present in the turn-off loop, the voltage between the gate electrode and the source electrode is maintained at a voltage lower than the threshold voltage.

With the above-described configuration, the gate charging current and discharging current can be individually and optimally adjusted as well as malfunction at the time of turn-on and turn-off can be prevented. Thus, it is possible to provide a switching circuit which is stably controlled by adjusting a switching speed of a high-speed switching device, and reducing the parasitic inductance in a drive circuit or damping the effect on the drive circuit by the parasitic inductance.

Also, the main switching device may have two parasitic capacitances one of which between the gate electrode and the source electrode and the other between the gate electrode and the drain electrode, and a resistance value of the first resistor may be a value greater than twice a square root of a quotient of an inductance value of the first parasitic inductance divided by a value of capacitance of a circuit in which the capacitor and a capacitor having a capacitance of a sum of the parasitic capacitances are connected in series.

Also, the main switching device may have two parasitic capacitances one of which between the gate electrode and the source electrode and the other between the gate electrode and the drain electrode, and a resistance value of the second resistor may be a value greater than a square root of a quotient of an inductance value of the second parasitic inductance divided by a value of capacitance of a circuit in which the capacitor and a capacitor having a capacitance of a sum of the parasitic capacitances are connected in series.

Consequently, voltage oscillation between the gate electrode and the source electrode at the time of turn-on and turn-off can be reduced, and thus malfunction prevention can be more reliably achieved.

Also, a capacitance value of the capacitor may be a value greater than a quotient of a gate charging charge of the main switching device divided by a voltage difference between a voltage value of the bias voltage source and the threshold voltage.

Consequently, the voltage between the gate electrode and the source electrode at the time of turn-on is higher than or equal to the threshold voltage, and thus turn-on operation can be reliably performed.

Also, the main switching device and at least part of the drive circuit may be mounted in a same chip or a same package.

Consequently, the circuit constant of the components of the drive circuit for driving the main switching device under an optimal condition can be set.

Also, when a voltage is applied between the gate electrode and the source electrode, the main switching device may allow a gate current to flow, and may have a diode characteristic such that a voltage between the gate electrode and the source electrode is clamped to a voltage having a gate-clamp voltage value, and the drive circuit may have a third resistor connected between the first switch element and the gate terminal.

Consequently, the gate current is supplied during an ON period, and thus the main switching device can be maintained at a low resistance.

Also, a capacitance value of the capacitor may be a value greater than a quotient of a gate charging charge of the main switching device divided by a voltage difference between a voltage value of the bias voltage source and the gate-clamp voltage value.

Consequently, a sufficient voltage is applied between the gate electrode and the source electrode at the time of turn-on, and thus turn-on operation can be reliably performed.

Also, the main switching device may have two parasitic capacitances one of which between the gate electrode and the source electrode and the other between the gate electrode and the drain electrode, and a resistance value of the first resistor may be set to a value greater than twice a square root of a quotient of an inductance value of the first parasitic inductance divided by a value of capacitance of a circuit in which the capacitor and a capacitor having a capacitance of a sum of the parasitic capacitances are connected in series, and the resistance value may be a value greater than a quotient of a voltage difference between a voltage value of the bias voltage source and the gate-clamp voltage value divided by a maximum rated value of the gate current.

Consequently, the voltage between the gate electrode and the source electrode at the time of turn-on, and the oscillation of flowing gate current can be damped, and the gate current can be set to a value lower than a maximum rated current.

Also, the switching circuit may further include a double-sided wiring board which includes a conductor for wiring on a front surface and a back surface. The main switching device and the drive circuit may be disposed on the front surface, a through hole may be provided, which is connected from a vicinity of each of the second source terminal, the negative electrode terminal, and a source terminal of the second switch element to a conductor for source wiring disposed on the back surface, and the conductor for source wiring may be disposed to include an area on the back surface of the double-sided wiring board, the area corresponding to an area of projection when the gate terminal, the second source terminal, and the drive circuit on the front surface of the double-sided wiring board are projected onto the back surface.

Consequently, the current which flows through the front surface and the current which flows through the back surface cancel generated magnetic fields each other, and thus a voltage generated by a parasitic inductance, which is present on the conductor for wiring, can be reduced.

Also, the conductor for source wiring may be disposed to be spaced apart from a conductor for wiring other than the conductor for source wiring disposed on the back surface.

Consequently, it is possible to protect against an adverse effect on other circuits by voltage fluctuations associated with an abrupt current which flows at the time of turn-on and turn-off.

Also, the switching circuit may further includes a wiring board which has conductors for wiring. The main switching device and the drive circuit may be disposed on a front surface of the wiring board, all of the conductors for wiring for connecting the main switching device and components included in the drive circuit may be disposed on the front surface, and the second source terminal, the negative electrode terminal, and a source terminal of the second switch element may be disposed to be adjacent to each other without any mounted component interposed between any two of the second source terminal, the negative electrode terminal, and the source terminal.

Consequently, it is possible to achieve short distance wiring of the conductor for source wiring which connects the source terminal for gate driving, the negative electrode terminal, and the source terminal of the second switch element. Thus, a voltage generated by a parasitic inductance, which is present on the conductor for wiring, is reduced, and a stably controlled switching operation without a malfunction can be performed.

With the switching circuit according to an aspect of the present disclosure, it is possible to provide a switching circuit capable of performing a switching operation which is stably controlled by adjusting a switching speed of a high-speed switching device, and reducing the parasitic inductance in a drive circuit or damping the effect on the drive circuit by the parasitic inductance.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is a circuit configuration diagram of a switching circuit according to Embodiment 1;

FIG. 2 is an operation timing chart of the switching circuit according to Embodiment 1;

FIG. 3 is a circuit configuration diagram of a switching circuit according to Embodiment 2;

FIG. 4A is a front-surface layout diagram of a double-sided wiring board in which the switching circuit according to Embodiment 2 is mounted;

FIG. 4B is a back-surface layout diagram of the double-sided wiring board in which the switching circuit according to Embodiment 2 is mounted.

FIG. 4C is a side view of the double-sided wiring board in which the switching circuit according to Embodiment 2 is mounted.

FIG. 5 is a mounting surface layout diagram of a single-sided wiring board in which a switching circuit according to Embodiment 3 is mounted.

FIG. 6 is a circuit diagram of a semiconductor circuit described in Japanese Unexamined Patent Application Publication No. 2011-77462.

### DETAILED DESCRIPTION OF THE EMBODIMENTS

Hereinafter, a switching circuit according to an embodiment of the present disclosure will be described with reference to the drawings. It is to be noted that each of the embodiments below illustrates a specific example of the present disclosure, and the numerical values, shapes, materials, components, arrangement positions and connection topologies of the components are examples, and not intended to limit the present disclosure.

### Embodiment 1

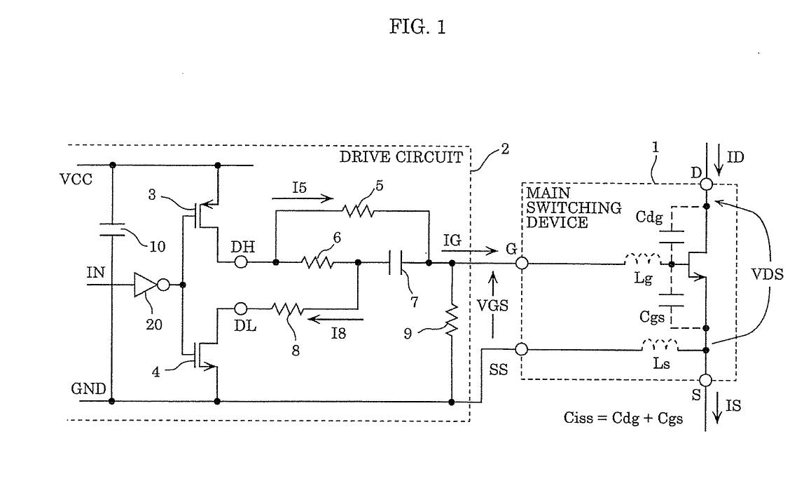

FIG. 1 is a circuit configuration diagram of a switching circuit according to Embodiment 1. The switching circuit illustrated in FIG. 1 includes a main switching device 1, and a drive circuit 2 that drives main switching device 1.

In FIG. 1, main switching device 1 is normally-off GaN transistor, and includes a semiconductor chip having a gate electrode, a drain electrode, and a source electrode, and has drain terminal D, gate terminal G, first source terminal S, and second source terminal SS. Gate terminal G is connected to the gate electrode, drain terminal D is connected to the drain electrode, first source terminal S and second source terminal SS are connected to the source electrode, and the main current of main switching device 1 flows through first source terminal S. Also second source terminal SS is a source terminal for gate driving connected to drive circuit 2. Hereinafter the gate electrode on the semiconductor chip of main switching device 1 is referred to as the gate, and is distinguished from gate terminal G. The source electrode is referred to as the source, and is distinguished from first source terminal S and second source terminal SS.

When gate-source voltage VGS of main switching device 1 is higher than or equal to threshold voltage Vth, main switching device 1 assumes an ON state, and the resistance between the drain and source becomes low, then the main current flows between the drain and source. Conversely, when gate-source voltage VGS is lower than threshold value voltage Vth, main switching device 1 assumes an OFF state, and a substantially open state is assumed between the drain and source. For the case of normally-off GaN transistor, threshold voltage Vth is of the order of 1V to 2V. In addition, the GaN transistor has a diode characteristic between the gate and source, and voltage VGS is clamped by voltage VGSF which is higher than threshold voltage Vth by of the order of 3V to 5V.

It is to be noted that the gate and gate terminal G, as well as the source, and first source terminal S, second source terminal SS have different potentials in a strict sense during an operation of a current of flowing, and only when a voltage difference matters, the potentials are to be distinguished. For instance, although gate-source voltage VGS is the voltage between the gate electrode and the source electrode according to the definition in the description, gate-source voltage VGS is substituted by gate terminal G-second source terminal SS voltage which is actually observed.

Also, main switching device 1 has parasitic capacitance Cdg between the drain and gate, and parasitic capacitance Cgs between the gate and source. A switching operation for drive circuit 2 is an operation of charging and discharging input capacitance Ciss=Cdg+Cgs is equivalently present between the gate and source.

In FIG. 1, drive circuit 2 includes bias capacitor 10, inverter 20, high-side switch 3, low-side switch 4, resistor 5, resistor 6, capacitor 7, resistor 8, and resistor 9.

Bias capacitor 10 is a bias voltage source that smoothes a supplied voltage, and supplies a bias voltage to drive circuit 2, and outputs bias voltage VCC from the positive electrode terminal, and the negative electrode terminal is connected to second source terminal SS of main switching device 1.

Inverter 20 logically inverts and outputs input drive signal IN.

High-side switch 3 is a PMOS transistor that is first switch element having a gate terminal, a source terminal, and drain terminal DH. An output of inverter 20 is inputted to the gate terminal of high-side switch 3, and bias voltage VCC is supplied to the source terminal.

Low-side switch 4 is an NMOS transistor that is second switch device having a gate terminal, a source terminal, and drain terminal DL. The source terminal of low-side switch 4 is connected to second source terminal SS of main switching device 1, and an output of inverter 20 is inputted to the gate terminal.

Resistor 5 is third resistor having one end connected to drain terminal DH of high-side switch 3 and the other end connected to gate terminal G of main switching device 1. Resistor 6 is first resistor having one end connected to drain terminal DH of high-side switch 3. Capacitor 7 has one end connected to the other end of resistor 6 and the other end connected to gate terminal G of main switching device 1. Resistor 8 is second resistor having one end connected to a connection point between resistor 6 and capacitor 7 and the other end connected to drain terminal DL of low-side switch 4.

With the above-described connection configuration, first series circuit, in which high-side switch 3, resistor 6, and capacitor 7 are connected in series, is formed between positive electrode terminal (VCC) and gate terminal G. In addition, second series circuit, in which capacitor 7, resistor 8, and low-side switch 4 are connected in series, is formed between gate terminal G and second source terminal SS.

Resistor 9 has one end connected to gate terminal G of main switching device 1 and other end connected to second source terminal SS. It is to be noted that resistor 9 is inserted to prevent malfunction which is caused by increase in the gate terminal voltage due to a leakage current at the time of stop of the switching circuit. The resistance is, for instance, 10 kΩ which is high, and its effect on the switching operation is almost negligible. Therefore, a description of resistor 9 will be omitted below.

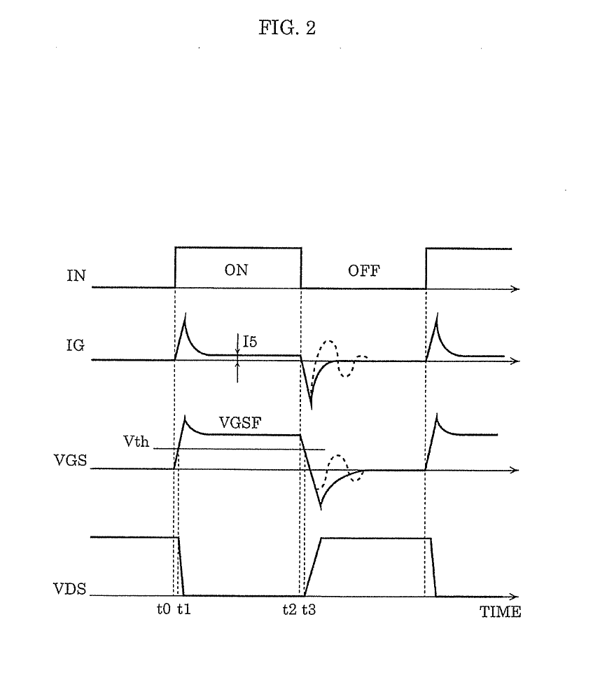

FIG. 2 is an operation timing chart of the switching circuit according to Embodiment 1. More specifically, FIG. 2 is a wave form chart of input drive signal IN, gate inflow current IG, gate-source voltage VGS, and drain voltage VDS in the switching circuit of FIG. 1. Hereinafter, the switching operation of the switching circuit of FIG. 1 will be described with reference to FIG. 2.

First, the operation in an ON period during which input drive signal IN is “H” (high level), in other words, the operation in which main switching device 1 is in an ON state will be described. Since input drive signal IN is “H”, and the gate terminal, to which an inverted signal is inputted, of high-side switch 3 is “L”, electrical connection is established between the source and drain of high-side switch 3, and the potential of drain terminal DH is substantially the same as the voltage value of bias voltage VCC.

In contrast, the gate terminal of low-side switch 4 is set to “L”, and thus electrical disconnection is achieved between the drain and source, and drain terminal DL is in an open state.

From drain terminal DH of high-side switch 3, a current through resistor 5, and a current through resistor 6 and a series circuit of capacitor 7 flow in gate terminal G of main switching device 1. In FIG. 2, at the initial stage of an ON period starting from time t0, the current flowing through resistor 6 and capacitor 7 is dominant in gate inflow current IG. The current rapidly charges capacitor 7 and input capacitance Ciss of main switching device 1 to increase gate-source voltage VGS. At time t1, when gate-source voltage VGS exceeds threshold voltage Vth, the impedance between the drain and source of main switching device 1 rapidly decreases, and thus drain voltage VDS also decreases, and transition to an ON state is made.

The current which flows through resistor 6 and capacitor 7 exponentially decreases as capacitor 7 is charged, and current I5 which flows through resistor 5 soon becomes dominant in gate inflow current IG. In order for normally-off GaN transistor to maintain a low resistance ON state, several mA to several tens mA of gate inflow current IG is necessary, and current IS, which flows through resistor 5, serves as gate inflow current IG. In the later stage of an ON period, gate-source voltage VGS is stabilized at gate clamp voltage VGSF.

Let Irg be the gate inflow current for maintaining an ON state, then for bias voltage VCC and gate clamp voltage VGSF, resistance R5 of resistor 5 needs to satisfy the following condition: R5<(VCC−VGSF)/Irg. For instance, when VCC=12V, VGSF=4V, and Irg=10 mA, then R5<800Ω, thus it is sufficient that 680Ω be selected as R5.

In other words, (1) when main switching device 1 applies gate-source voltage VGS, gate inflow current (Irg) flows, and main switching device 1 has a diode characteristic such that the voltage between the gate electrode and the source electrode is clamped by gate clamp voltage VGSF, and (2) since drive circuit 2 has resistor 5 connected between high-side switch 3 and gate terminal G, the gate current is supplied during an ON period, and thus main switching device 1 can be maintained at a low resistance.

Meanwhile, maximum rated value Ig_max is defined for the gate inflow current, which regularly flows into GaN transistor, and the following condition is also necessary: R5>(VCC−VGSF)/Ig_max. However, since gate inflow current Irg flows during an ON period, when a current more than necessary is passed by reducing resistance R5, loss of drive circuit 2 is increased. For this reason, a value close to an upper limit may be selected for resistance R5.

Let Qg be the charging electric charge for charging gate-source voltage VGS up to gate clamp voltage VGSF, then capacitance value C7 of capacitor 7 needs to satisfy the following condition: C7>Qg/(VCC−VGSF). In other words, capacitance value C7 needs to be greater than the quotient of charging electric charge Qg divided by the voltage difference between voltage VCC of the bias voltage source and gate clamp voltage VGSF. For instance, when Qg=8 nC, C7>1000 pF, and it is sufficient that 1000 pF be selected as C7. Consequently, a sufficient voltage is applied between the gate electrode and the source electrode at the time of turn-on, and thus turn-on operation can be reliably performed.

When main switching device 1 has no gate clamp voltage VGSF and does not need gate inflow current for maintaining an ON state like MOSFET, resistor 5 is unnecessary, and threshold voltage Vth may be used instead of gate clamp voltage VGSF in the aforementioned conditional expression. Specifically, it is sufficient that capacitance value C7 of capacitor 7 satisfy the following condition: C7>Qg/(VCC−Vth). In other words, it is sufficient that capacitance value C7 be greater than the quotient of charging electric charge Qg divided by the voltage difference between voltage value VCC of the bias voltage source and threshold voltage Vth. Consequently, gate-source voltage VGS at the time of turn-on is higher than or equal to threshold voltage Vth, and thus turn-on operation can be reliably performed.

At the initial stage of an ON period, resistor 6 adjusts gate inflow current IG, and also takes a role in oscillation damping. First, the adjustment of gate inflow current IG will be described. The gate inflow current of GaN transistor, excluding the charging current to input capacitance Ciss of main switching device 1 has a maximum rated value Igp at a peak value. Resistance R6 of resistor 6 needs to satisfy the following condition: R6>(VCC−VGSF)/Igp. In other words, resistance R6 needs to be greater than the quotient of the voltage difference between voltage VCC of the bias voltage source and gate clamp voltage VGSF divided by maximum rated value Igp of the gate inflow current. For instance, when Igp=1.5 A, R6>5.3Ω, and it is sufficient that 6.2Ω be selected as R6. Consequently, the gate current can be adjusted to the maximum rated current or lower. When main switching device 1 has a high input impedance of gate terminal G and has no maximum rated value for the inflow current like MOSFET, the aforementioned condition does not need to be considered.

Next, an oscillation damping function of resistor 6 will be described. A first parasitic inductance is present in the turn-on loop formed by positive electrode (VCC) of bias capacitor 10-high-side switch 3-resistor 6-capacitor 7-the gate of main switching device 1-second source terminal SS-negative electrode (GND) of bias capacitor 10. In FIG. 1, Lg between the gate electrode of main switching device 1 and gate terminal G, and Ls between the source electrode of main switching device 1 and second source terminal SS are written. Let L1 be the total of parasitic inductances present in the turn-on loop, including Lg and Ls. At the initial stage of an ON period, when oscillation occurs between first parasitic inductance L1 and the capacitance C=C7×Ciss/(C7+Ciss) of a circuit in which capacitor 7 and a capacitor having input capacitance Ciss are connected in series, voltage VGS between the gate electrode and the source electrode is reduced lower than the threshold, and an OFF state is assumed, which may cause a malfunction. When the effect of other circuit constants are neglected, the condition for oscillation damping which is overdamping is expressed by the following Expression 1.

$$R 6 > 2 \sqrt{\frac{L 1}{C}} \qquad [ Expression 1 ]$$

Specifically, Expression 1 indicates that the resistance of resistor 6 is a value greater than twice the square root of the quotient of first parasitic inductance L1 divided by series capacitance value C for capacitance value C7 of capacitor 7 and input capacitance Ciss, the series capacitance value C being the capacitance of a circuit in which an inductor having inductance L1 and capacitor 7 are connected in series.

For instance, when C=500 pF and L1=4 nH, R6>5.665, and 6.2Ω is sufficient as R6 mentioned above.

Consequently, oscillation of gate-source voltage VGS at the time of turn-on can be damped, and thus malfunction prevention can be more reliably achieved.

Specifically, when high-side switch 3 is in an ON state, and a current flows through the turn-on loop formed by bias capacitor 10, first series circuit, and main switching device 1, even when a voltage drop occurs in the turn-on loop by first parasitic inductance L1 present in the turn-on loop, gate-source voltage VGS is maintained at a voltage higher than or equal to threshold voltage Vth.

Next, the operation in an OFF period during which input drive signal IN is “L” (low level), in other words, the operation in which main switching device 1 is in an OFF state will be described. Since input drive signal IN is “L”, and the gate terminal, to which an inverted signal is inputted, of high-side switch 3 is “H”, electrical disconnection is achieved between the source and drain of high-side switch 3, and drain terminal DH is in an open state.

In contrast, the gate terminal of low-side switch 4 is set to “H”, and thus a conductive state is achieved between the drain and source, and drain terminal DL has GND potential.

No inflow current from drain terminal DH of high-side switch 3 flows into gate terminal G of main switching device 1, and conversely, a current flows out via a series circuit formed by capacitor. 7, resistor 8, and low-side switch 4. The current rapidly discharges capacitor 7 and input capacitance Ciss of main switching device 1 to reduce gate-source voltage VGS. At time t3, when gate-source voltage VGS falls below threshold voltage Vth, the impedance between the drain and source of main switching device 1 rapidly increases, and thus drain voltage VDS increases, and transition to an OFF state is made.

At the initial stage of an OFF period, resistor 5, resistor 6, and the later-described parasitic inductance are neglected, and let C be the series capacitance value for capacitor 7 and input capacitance Ciss of main switching device 1, then gate-source voltage VGS is expressed by the following Expression 2.

$$VGS = VGSF - \frac{C 7}{C 7 + Ciss} \cdot VCC \cdot [ 1 - exp ( - \frac{t}{C \cdot R 8} ) ] \qquad [ Expression 2 ]$$

Time constant C·R8 is set to several ns, and thus gate-source voltage VGS reaches the value expressed by the following Expression 3 in around 10 ns.

$$VGSF - \frac{C 7}{C 7 + Ciss} \cdot VCC \qquad [ Expression 3 ]$$

For instance, when Ciss=750 pF, gate-source voltage VGS is −4V, and quickly has a negative voltage at the time of turn-off of main switching device 1. Subsequently, capacitor 7 and input capacitance Ciss are discharged by series resistance of resistor 5 and resistor 6, and resistor 9 during an OFF period, and reach substantially 0V by the time of completion of the OFF period.

However, a second parasitic inductance is present in the turn-off loop formed by the gate of main switching device 1-gate terminal G-capacitor 7-resistor 8-low-side switch 4-second source terminal SS-the source of main switching device 1. Let L2 be the total of parasitic inductances including the above-described Lg and Ls. At the initial stage of the OFF period described above, when oscillation occurs between the series capacitance C formed by capacitor 7 and input capacitance Ciss, and second parasitic inductance L2, as indicated by a dashed line of FIG. 2, gate inflow current IG (in this case, gate outflow current IG) and gate-source voltage VGS cause oscillation. The oscillation may cause not only noise, but also increase gate-source voltage VGS during turn-off, and an ON state is assumed, which may cause a malfunction. Resistor 8 limits the peak value of gate outflow current IG, and also takes a role in damping oscillation which is caused by the presence of parasitic inductance L2. When the effect of other circuit constants are neglected, the condition for oscillation damping which is overdamping is expressed by the following Expression 4.

$$R 8 > 2 \sqrt{\frac{L 2}{C}} \qquad [ Expression 4 ]$$

For instance, when C=500 pF, L=4 nH, R8>5.66Ω. It is to be noted that Expression 4 provides the condition for overdamping to prevent oscillation, and when it is sufficient that oscillation be damped to an extent in which a switching operation is not interfered with, this is not the case. The condition is expressed by the following Expression 5.

$$R 8 > \sqrt{\frac{L 2}{C}} \qquad [ Expression 5 ]$$

As presented in Expression 5, when it is sufficient that oscillation be damped to an extent in which a switching operation is not interfered with, R8 can be relaxed to the range of 1Ω to 10Ω.

Specifically, Expression 5 indicates that the resistance of resistor 8 is a value greater than the square root of the quotient of second parasitic inductance L2 divided by series capacitance value C for capacitance value C7 of capacitor 7 and input capacitance Ciss, the series capacitance value C being the capacitance of a circuit in which an inductor having inductance L2 and capacitor 7 are connected in series.

Consequently, oscillation of gate-source voltage VGS at the time of turn-off can be damped, and thus malfunction prevention can be more reliably achieved.

Specifically, when low-side switch 4 is in an ON state, and a current flows through the turn-off loop formed by main switching device 1 and second series circuit, even when a voltage drop occurs in the turn-off loop by second parasitic inductance L2 present in the turn-off loop, gate-source voltage VGS is maintained at a voltage lower than threshold voltage Vth.

In the switching circuit according to the embodiment, drain current ID, which flows through drain terminal D of main switching device 1, flows from the source electrode through first source terminal S as source current IS by a switching operation of main switching device 1. Therefore, second source terminal SS branched from the source electrode is hardly affected by source current IS. This is the reason why only the gate loop needs to be considered in the setting of resistor 6 and resistor 8 described above.

As described above, in the switching circuit according to the embodiment, due to the configuration in which one of terminals branched from the source of main switching device 1 is connected to drive circuit 2, it is possible to eliminate the effect of the main current which flows between the drain and source. Furthermore, the gate current paths at the time of turn-on and turn-off are separated, and thus each current can be adjusted and oscillation of the waveform of gate current/voltage can be damped.

In Embodiment 1, inverter 20, high-side switch 3, and low-side switch 4 have been described as separate components included in drive circuit 2. However, driver IC which is an integrated circuit may be used for those components. Also, when main switching device 1 is selected, constants can be set to the components such as resistors 5, 6, 8, and 9 and capacitor 7 so that main switching device 1 is driven under optimal conditions. Therefore, main switching device 1, and drive circuit components such as resistors and capacitors may be mounted in the same chip or the same package.

### Embodiment 2

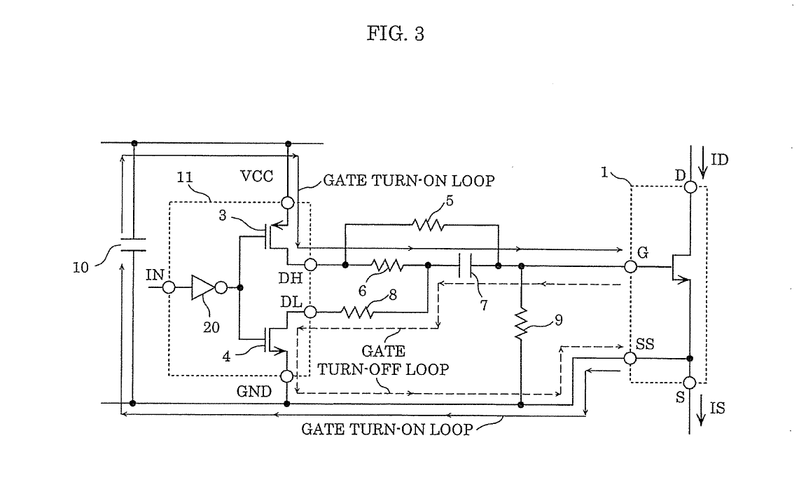

FIG. 3 is a circuit configuration diagram of a switching circuit according to Embodiment 2. In contrast to the switching circuit according to Embodiment 1, the switching circuit according to this embodiment includes drive unit 11 in which inverter 20, high-side switch 3, and low-side switch 4 are integrated, and a double-sided wiring board having a conductor for wiring on each of the front surface and the back surface. In FIG. 3, a gate turn-on loop (solid line arrow), and a gate turn-off loop (dashed line arrow) are illustrated.

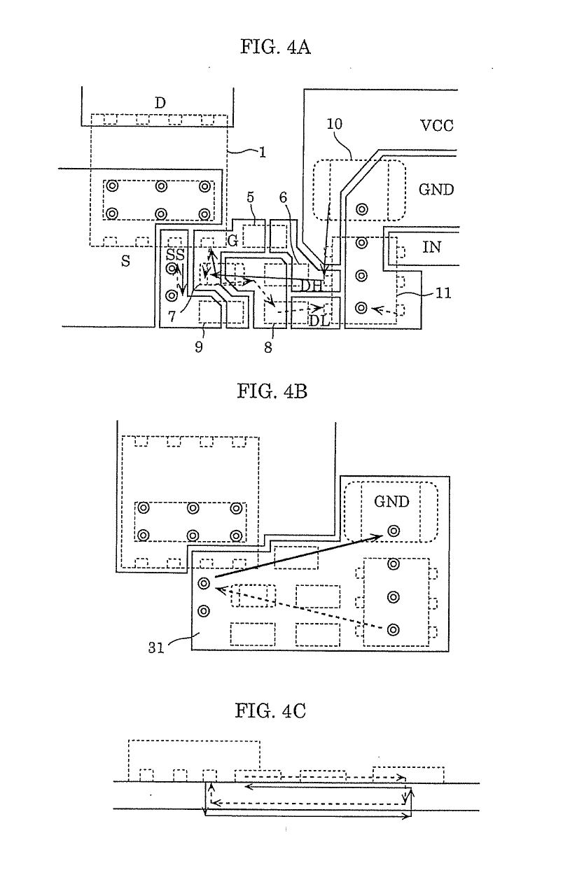

Also, FIG. 4A is a front-surface layout diagram of a double-sided wiring board in which the switching circuit according to Embodiment 2 is mounted. FIG. 4B is a back-surface layout diagram of the double-sided wiring board in which the switching circuit according to Embodiment 2 is mounted. It is to be noted that in FIG. 4B, in order to facilitate the understanding of relation of connection between the front surface and the back surface, an inverted mirror image of the actual layout is illustrated as if the back-surface layout diagram is seen from the front surface side. FIG. 4C is a side view of the double-sided wiring board in which the switching circuit according to Embodiment 2 is mounted. FIGS. 4A to 4C illustrate the gate turn-on loop (solid line arrow), and the gate turn-off loop (dashed line arrow) depicted in FIG. 3. It is to be noted that each double circle in FIGS. 4A and 4B indicates a through hole which allows the front-surface wiring conductor and the back-surface wiring conductor to be connected.

As illustrated in FIG. 4A, the components of drive circuit 2 and wires for connecting main switching device 1 and the components are disposed on the front surface of the double-sided wiring board. As illustrated in FIG. 4B, conductor 31 for source wiring is provided via multiple through holes on the back surface of the double-sided wiring board.

The through holes allow second source terminal SS, negative electrode terminal GND and the source terminal of low-side switch 4 included in drive unit 11, and conductor 31 for source wiring on the back surface to be connected.

In other words, conductor 31 for source wiring is disposed to include an area on the back surface, the area corresponding to an area of projection when gate terminal G and second source terminal SS of main switching device 1, and the components included in drive circuit 2 disposed on the front surface are projected onto the back surface.

With the disposition in this manner, for the current which flows through the front surface, the same current flows through the back surface in the opposite direction at the time of turn-on as well as at the time of turn-off. Thus, generated magnetic fields cancel each other, and a voltage generated by a parasitic inductance, which is present on the conductor for wiring, can be reduced.

Also, conductor 31 for source wiring may be independently separated without being shared by other wires even at the same potential. In other words, conductor 31 for source wiring may be disposed to be spaced apart from the conductors for wiring other than conductor 31 for source wiring disposed on the back surface. In this manner, conductor 31 for source is not shared with other conductors for wiring, particularly, conductors for wiring small signal circuits, and thus, it is possible to protect against an adverse effect on other circuits by voltage fluctuations associated with an abrupt current which flows at the time of turn-on and turn-off.

### Embodiment 3

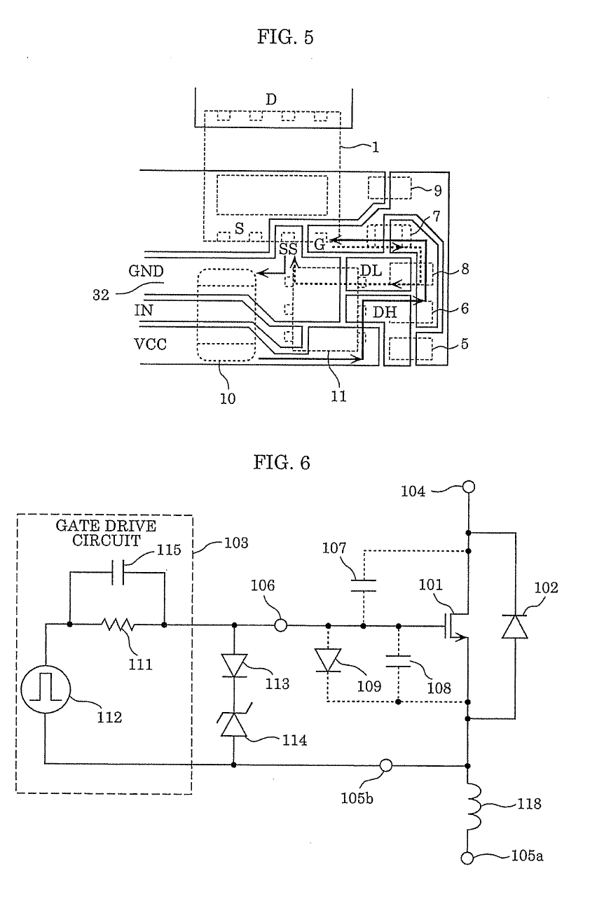

FIG. 5 is a mounting surface diagram of a single-sided wiring board in which a switching circuit according to Embodiment 3 is mounted. The switching circuit according to this embodiment differs from the switching circuit according to Embodiment 2 in that a single-side wiring board is used. Specifically, main switching device 1 and drive circuit 2 are disposed on the front surface of the wiring board, and all the conductors for wiring, which connect main switching device 1 and the components included in drive circuit 2, are disposed on the front surface. For this reason, it is difficult for the switching circuit according to this embodiment to adopt a wiring configuration in which magnetic fields are cancelled each other.

Thus, main switching device 1, bias capacitor 10, and drive unit 11 are disposed to be adjacent to each other, and any another component is not disposed between these, and conductor 32 for source wiring is disposed, in which second source terminal SS of main switching device 1, the negative electrode of bias capacitor 10, and the source terminal of low-side switch 4 in drive unit 11 are connected within a short distance.

With the disposition in this manner, parasitic inductance present in conductor 32 for source wiring in the gate loop can be reduced, and a voltage generated by a parasitic inductance at the time of turn-on and turn-off can be reduced.

Needless to say, in Embodiments 2 and 3, each loop is to be short and thick, and the area surrounding each loop is to be small according to the fundamental of a high frequency large current pattern design.

### Other Embodiments

Although the switching circuit of the present disclosure has been described based on the embodiments, the switching circuit of the present disclosure is not limited to Embodiments 1 to 3.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

What is claimed is:

1. A switching circuit, comprising:
a main switching device; and
a drive circuit,
wherein the main switching device includes:
a drain electrode;
a gate electrode; and
a source electrode,
wherein when the main switching device is in an ON state where a voltage higher than or equal to a threshold voltage is applied between the gate electrode and the source electrode, a main current flows between the drain electrode and the source electrode,
wherein the main switching device further includes:
a gate terminal connected to the gate electrode;
a drain terminal connected to the drain electrode;
a first source terminal which is connected to the source electrode and through which the main current flows; and
a second source terminal for gate drive connected to the source electrode and the drive circuit,
wherein the drive circuit includes:
a bias voltage source having a negative electrode terminal connected to the second source terminal, and a positive electrode terminal;
a first series circuit formed between the positive electrode terminal and the gate terminal by connecting a first switch element, a first resistor, and a capacitor in series; and
a second series circuit formed between the gate terminal and the second source terminal by connecting the capacitor, a second resistor, and a second switch element in series,
wherein when the first switch element is in an ON state, and a current flows through a turn-on loop formed by the bias voltage source, the first series circuit, and the main switching device, even when a voltage drop occurs in the turn-on loop by a first parasitic inductance present in the turn-on loop, the voltage between the gate electrode and the source electrode is maintained at a voltage higher than or equal to the threshold voltage, and
when the second switch element is in an ON state, and a current flows through a turn-off loop formed by the main switching device and the second series circuit, even when a voltage drop occurs in the turn-off loop by a second parasitic inductance present in the turn-off loop, the voltage between the gate electrode and the source electrode is maintained at a voltage lower than the threshold voltage.

2. The switching circuit according to claim 1,
wherein the main switching device has two parasitic capacitances one of which between the gate electrode and the source electrode and the other between the gate electrode and the drain electrode, and
a resistance value of the first resistor is a value greater than twice a square root of a quotient of an inductance value of the first parasitic inductance divided by a value of capacitance of a circuit in which the capacitor and an equivalent capacitor having a capacitance of a sum of the parasitic capacitances are connected in series.

3. The switching circuit according to claim 1,
wherein the main switching device has two parasitic capacitances one of which between the gate electrode and the source electrode and the other between the gate electrode and the drain electrode, and
a resistance value of the second resistor is a value greater than a square root of a quotient of an inductance value of the second parasitic inductance divided by a value of capacitance of a circuit in which the capacitor and an equivalent capacitor having a capacitance of a sum of the parasitic capacitances are connected in series.

4. The switching circuit according to claim 1,
wherein a capacitance value of the capacitor is a value greater than a quotient of a gate charging charge of the main switching device divided by a voltage difference between a voltage value of the bias voltage source and the threshold voltage.

5. The switching circuit according to claim 1,
wherein the main switching device and at least part of the drive circuit are mounted in a same chip or a same package.

6. The switching circuit according to claim 1,
wherein when a voltage is applied between the gate electrode and the source electrode, the main switching device allows a gate current to flow, and has a diode characteristic such that a voltage between the gate electrode and the source electrode is clamped to a voltage having a gate-clamp voltage value, and
the drive circuit has a third resistor connected between the first switch element and the gate terminal.

7. The switching circuit according to claim 6,
wherein a capacitance value of the capacitor is a value greater than a quotient of a gate charging charge of the main switching device divided by a voltage difference between a voltage value of the bias voltage source and the gate-clamp voltage value.

8. The switching circuit according to claim 6,
wherein the main switching device has two parasitic capacitances one of which between the gate electrode and the source electrode and the other between the gate electrode and the drain electrode, and
a resistance value of the first resistor is set to a value greater than twice a square root of a quotient of an inductance value of the first parasitic inductance divided by a value of capacitance of a circuit in which the capacitor and an equivalent capacitor having a capacitance of a sum of the parasitic capacitances are connected in series, and the resistance value is a value greater than a quotient of a voltage difference between a voltage value of the bias voltage source and the gate-clamp voltage value divided by a maximum rated value of the gate current.

9. The switching circuit according to claim 1, further comprising
a double-sided wiring board which includes a conductor for wiring on a front surface and a back surface,
wherein the main switching device and the drive circuit are disposed on the front surface,
a through hole is provided, which is connected from a vicinity of each of the second source terminal, the negative electrode terminal, and a source terminal of the second switch element to a conductor for source wiring disposed on the back surface, and
the conductor for source wiring is disposed to include an area on the back surface of the double-sided wiring board, the area corresponding to an area of projection when the gate terminal, the second source terminal, and the drive circuit on the front surface of the double-sided wiring board are projected onto the back surface.

10. The switching circuit according to claim 9,
wherein the conductor for source wiring is disposed to be spaced apart from a conductor for wiring other than the conductor for source wiring disposed on the back surface.

11. The switching circuit according to claim 1, further comprising
a wiring board which has conductors for wiring,
wherein the main switching device and the drive circuit are disposed on a front surface of the wiring board,
all of the conductors for wiring for connecting the main switching device and components included in the drive circuit are disposed on the front surface, and
the second source terminal, the negative electrode terminal, and a source terminal of the second switch element are disposed to be adjacent to each other without any mounted component interposed between any two of the second source terminal, the negative electrode terminal, and the source terminal.
